(19) United States
(12) Patent Application Publication
(10) Pub. No.: US 2010/0042237 A1
(43) Pub. Date: Feb. 18, 2010

(54) MOBILE COMMUNICATION DEVICE AND AUDIO SIGNAL ADJUSTING METHOD THEREOF

(75) Inventor: KUAN-HSUEH LEE, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication Systems, Inc., Tu-Cheng City (TW)

(21) Appl. No.: 12/509,032

(22) Filed: Jul. 24, 2009

(30) Foreign Application Priority Data
Aug. 15, 2008 (CN) 200810303858.X

(51) Int. Cl. G06F 17/00; H03F 99/00; H04B 15/00; H04B 1/00

(52) U.S. Cl. 700/94; 381/120; 381/94.1; 381/119

(57) ABSTRACT

A mobile communication device includes an audio receiving unit, an audio adjusting unit, and an audio output unit. The audio receiving unit receives audio signals. The audio adjusting unit adjusts the audio signals and amplifies the audio signals of a predetermined frequency band. The audio output unit outputs the adjusted audio signals received from the audio adjusting unit.

### BACKGROUND

1. Technical Field

The disclosure generally relates to mobile communication devices, particularly to a mobile communication device with received audio signal adjusting function and an audio signal adjusting method.

2. Description of Related Art

The frequency band of audio signals are divided into the low frequency band of 30 Hz-˜50 Hz, the middle-low frequency band of 150 Hz˜500 Hz, the middle-high frequency band of 500 Hz˜5 KHz, and the high frequency band of 5 KHz˜16 KHz according to International Electronic Commission (IEC) criterion. People usually can hear the audio signals at frequency band of 20 Hz˜20 KHz. However, people's hearing may degenerate with age and/or due to environmental conditions such as exposure to loud noise in the workplace, and thus have difficulty hearing high frequency audio signals. So when such people use mobile communication devices to communicate with others, they may need to adjust the volume to a higher level to hear more clearly.

Conventional communication devices usually involve adjusting the volume of received audio higher by means of amplifying the entire frequency band of the audio signals. Adjusting audio signals by this way amplifies the high frequency band and low frequency band of the audio signals at same time, and increasing the volume of the lower frequency band of the audio signals may mask the high frequency band, causing part of the high frequency band of the audio signals to be lost.

Therefore, there is room for improvement within the art.

### BRIEF DESCRIPTION OF THE DRAWINGS

Many aspects of the mobile communication device with audio signal adjusting function and audio signal adjusting method thereof can be better understood with reference to the following drawings. The components in the drawings are not necessarily drawn to scale, the emphasis instead being placed upon clearly illustrating the principles of the mobile communication device with audio signals adjusting function and the audio signals adjusting method thereof.

FIG. 1 shows a block diagram of a mobile communication device in accordance with an exemplary embodiment.

FIG. 2 shows a flow chart of an audio signal adjusting process of the mobile communication device shown in FIG. 1.

### DETAILED DESCRIPTION

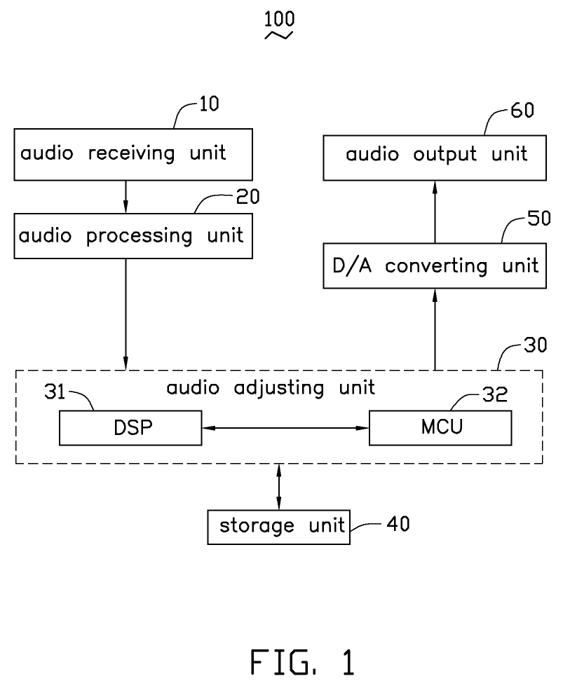

Referring to FIG. 1, a mobile communication device 100 includes an audio receiving unit 10, an audio processing unit 20, an audio adjusting unit 30, a storage unit 40, a digital/analog (D/A) converting unit 50 and an audio output unit 60. The audio receiving unit 10, the audio processing unit 20, the audio adjusting unit 30, the D/A converting unit 50 and the audio output unit 60 are electronically connected in series, and the storage unit 40 is electronically connected to the audio adjusting unit 40.

The audio receiving unit 10 receives audio signals from other electronic elements of the mobile communication devices 100 such as a radio frequency (RF) circuit and sends the audio signals to the audio processing unit 20.

The audio processing unit 20 reduces noise in the audio signals received from the audio receiving unit 10, and sends the processed audio signals to the audio adjusting unit 30. The audio processing unit 20 may be a filter of the mobile communication device 100.

The audio adjusting unit 30 includes a digital signal processer (DSP) 31 and a micro controller unit (MCU) 32. The DSP 31 decodes the audio signals received from the audio processing unit 20, and sends the decoded audio signals to the MCU 32. The MCU 32 analyzes the decoded audio signals, and separates the audio signals of the frequency band which needs to be adjusted from the decoded audio signals, and amplifies the separated audio signals to a predetermined level. The frequency band of audio signals which needs to be adjusted may be predetermined by the users according to their own hearing abilities. Finally, the MCU 32 remixes the amplified audio signals with the remaining decoded audio signals. For example, for some users having difficulty in hearing high frequency audio signals, the MCU 32 can be set to separate audio signals at a high frequency band of 5 KHz˜20 KHz from the entire audio signals, and then amplify those audio signals to a predetermined level, and finally remix the amplified audio signals with of the remaining audio signals of the entire audio signals.

The storage unit 40 stores the audio signals after being adjusted by the audio adjusting module 30. The storage unit 40 is a module capable of inputting and outputting information such as a hard disk, flash memory, or a secure digital (SD) card.

The D/A converting unit 50 receives the adjusted audio signals from the audio adjusting module 30 and then converts the adjusted audio signals to analog audio signals.

The audio output unit 60 outputs the analog audio signals for users of the mobile communication device 100. The audio output unit 60 may be a speaker mounted in the mobile communication device 100.

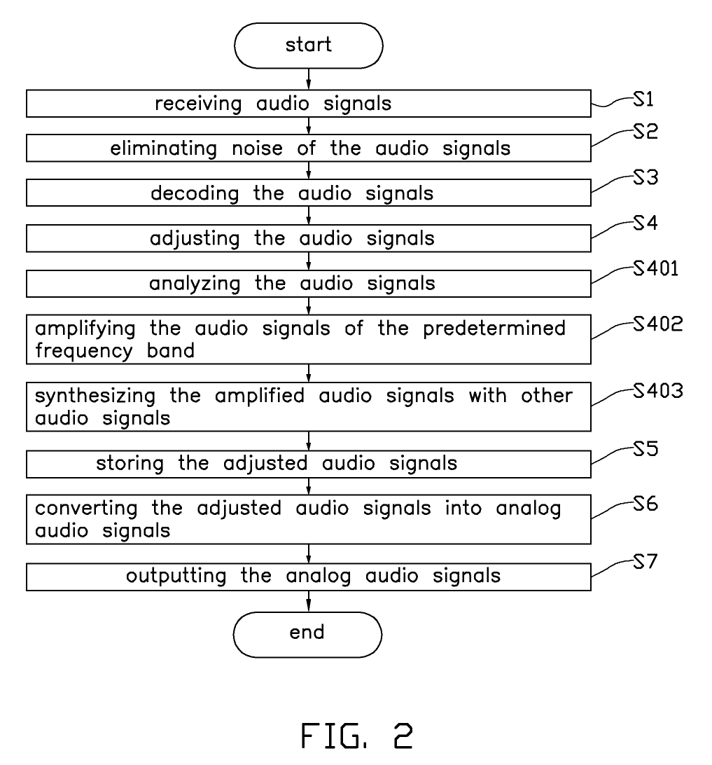

Referring to FIG. 2, the audio adjusting method of the mobile communication device 100 may include the following steps:

In step S1, the audio receiving unit 10 receives audio signals, and then sends the received audio signals to the audio processing unit 20.

In step S2, the audio processing unit 20 reduces noise of the audio signals, and then sends the audio signals to audio adjusting unit 30.

In step S3, the DSP 31 decodes the audio signals received from the audio processing unit 20, and then sends the decoded audio signals to the MCU 32.

In step S4, the MCU 32 adjusts the audio signals, this step may include the following sub-steps:

In sub-step S401, the MCU 32 analyzes the audio signals.

In sub-step S402, the MCU 32 separates audio signals of the predetermined frequency band which needs to be adjusted from the decoded audio signals, and amplifies the separated audio signals to a predetermined level.

In sub-step S403, the MCU 32 remixes the amplified digital audio signals with the remaining decoded audio signals, and sends the adjusted audio signals to the D/A converting unit 50 and the storage unit 40.

In step S5, the storage unit 40 stores the adjusted audio signals received from the MCU 32.

In step S6, the D/A converting unit 50 converts the adjusted audio signals into analog audio signals.

In step S7, the audio output unit 60 outputs the analog audio signals received from the D/A converting unit 50.

The mobile communication device 100 amplifies the audio signals of predetermined frequency band, avoids generating making effect by means of amplifying entire frequency band of the audio signals, and finally obtains an improved audio effect.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A mobile communication device, comprising:
an audio receiving unit receiving audio signals;
an audio adjusting unit adjusting the audio signals and amplifying the audio signals of a predetermined frequency band; and
an audio output unit outputting the adjusted audio signals received from the audio adjusting unit.

2. The mobile communication device as claimed in claim 1, further comprising a D/A converting unit set between the audio adjusting unit and the audio output unit to convert the audio signals to analog audio signals.

3. The mobile communication device as claimed in claim 1, further comprising a audio processing unit set between the audio receiving unit and the audio adjusting unit to reduce noise in the audio signals.

4. The mobile communication device as claimed in claim 1, further comprising a storage unit connected to the audio adjusting unit to store the adjusted audio signals.

5. The mobile communication device as claimed in claim 1, wherein the audio adjusting unit includes a DSP for decoding the audio signals.

6. The mobile communication device as claimed in claim 5, wherein the audio adjusting unit further includes a MCU for receiving the decoded audio signals from the DSP, and then amplifying the decoded audio signals of a predetermined frequency band, finally remixing the amplified audio signals with the remaining decoded audio signals.

7. An audio signal adjusting method, comprising:
receiving audio signals;
adjusting the audio signals, comprising
amplifying the audio signals of a predetermined frequency band; and
outputting the audio signals.

8. The audio signal adjusting method as claimed in claim 7, further comprising reducing noise of the audio signals after receiving audio signals.

9. The audio signal adjusting method as claimed in claim 7, further comprising remixing the amplified audio signals with remaining audio signals of the entire audio signals after amplifying the audio signals at the predetermined frequency band.

10. The audio signal adjusting method as claimed in claim 7, further comprising storing the adjusted audio signals after adjusting the audio signals.

11. The audio signal adjusting method as claimed in claim 7, further comprising converting the adjusted audio signals into analog audio signals before outputting the audio signals.
